(19) United States
(12) Patent Application Publication
(10) Pub. No.: US 2025/0338663 A1
(43) Pub. Date: Oct. 30, 2025

(54) ELECTRONIC COMPONENT AND APPARATUS

(71) Applicant: CANON KABUSHIKI KAISHA, Tokyo (JP)

(72) Inventor: YU KATASE, Kanagawa (JP)

(21) Appl. No.: 19/187,171

(22) Filed: Apr. 23, 2025

(30) Foreign Application Priority Data
Apr. 30, 2024 (JP) 2024-074047

(51) Int. Cl. H10F 39/00; H01L 23/00

(52) U.S. Cl. CPC H10F 39/811; H01L 24/48; H10F 39/804; H01L 2224/48096; H01L 2224/48227

(57) ABSTRACT

An electronic component including a support substrate and a photoelectric conversion substrate is provided. The photoelectric conversion substrate includes a photoelectric conversion region and a peripheral region in which a first electrode is arranged. The first electrode is connected to a second electrode arranged on the support substrate via a wire. A first portion, arranged on the photoelectric conversion substrate, of the wire includes at least one bent portion, the wire is arranged within a range of not more than 200 μm from a surface of the first electrode, and a portion, from the first electrode to a first height, of the first portion has a maximum angle not larger than 30° with respect to a normal direction of the surface where the first height is ½ of a maximum height of the wire from the surface.

### BACKGROUND OF THE INVENTION

### Field of the Invention

The present disclosure relates to an electronic component and an apparatus.

### Description of the Related Art

Japanese Patent Laid-Open No. 5-275668 discloses a solid-state image capturing apparatus including a solid-state image sensor, a transparent plate arranged to face the solid-state image sensor, and a bonding wire connected to an electrode arranged on the periphery of the optical imaging surface of the solid-state image sensor. Japanese Patent Laid-Open No. 5-275668 describes a design guideline for suppressing a ghost occurring when incident light is reflected by the bonding wire and the reflected light is further reflected by the transparent plate to enter the optical imaging surface.

### SUMMARY OF THE INVENTION

Some embodiments of the present disclosure provide a technique advantageous in further suppressing occurrence of a ghost caused by a conductive wire.

According to some embodiments, an electronic component comprising a support substrate, a photoelectric conversion substrate fixed to the support substrate, and an optical member arranged to face the photoelectric conversion substrate, wherein the photoelectric conversion substrate includes a main surface including a photoelectric conversion region in which a plurality of photoelectric conversion elements are arranged and a peripheral region in which a first electrode is arranged, the first electrode is connected, via a conductive wire, to a second electrode arranged on the support substrate, a first portion, arranged on the photoelectric conversion substrate, of the conductive wire includes at least one bent portion, the conductive wire is arranged within a range of not more than 200 μm from a surface of the first electrode in a normal direction of the surface, and a portion, from the first electrode to a first height, of the first portion has a maximum angle not larger than 30° with respect to the normal direction where the first height is ½ of a maximum height of the conductive wire from the surface in the normal direction, is provided.

Further features of the present invention will become apparent from the following description of exemplary embodiments (with reference to the attached drawings).

### BRIEF DESCRIPTION OF THE DRAWINGS

FIG. 1 is a sectional view showing an example of the arrangement of an electronic component according to an embodiment;

FIG. 2 is a plan view showing an example of the arrangement of the electronic component shown in FIG. 1;

FIG. 3 is a view for explaining occurrence of a ghost caused by a conductive wire;

FIGS. 4A to 4F are views for explaining occurrence of a ghost caused by the conductive wire;

FIGS. 5A to 5D are sectional views each showing an example of the arrangement of the electronic component shown in FIG. 1;

FIGS. 6A to 6D are sectional views each showing an example of the arrangement of the electronic component shown in FIG. 1;

FIG. 7 is a sectional view showing an example of the arrangement of the electronic component shown in FIG. 1;

FIG. 8 is a sectional view showing an example of the arrangement of the electronic component shown in FIG. 1;

FIGS. 9A and 9B are sectional views each showing an example of the arrangement of the electronic component shown in FIG. 1;

FIG. 10 is a sectional view showing a modification of the electronic component shown in FIG. 1;

FIG. 11 is a plan view showing an example of the arrangement of the electronic component shown in FIG. 10; and

FIG. 12 is a view showing an example of the arrangement of an apparatus incorporating the electronic component shown in FIG. 1.

### DESCRIPTION OF THE EMBODIMENTS

Hereinafter, embodiments will be described in detail with reference to the attached drawings. Note, the following embodiments are not intended to limit the scope of the claimed invention. Multiple features are described in the embodiments, but limitation is not made to an invention that requires all such features, and multiple such features may be combined as appropriate. Furthermore, in the attached drawings, the same reference numerals are given to the same or similar configurations, and redundant description thereof is omitted.

In the following description, terms (for example, “upper”, “lower”, “right”, “left” and other terms including these terms) representing specific directions or positions are used, as necessary. These terms are used for easy understanding of the embodiments with reference to the accompanying drawings, and the meanings of the terms do not limit the technical scope of the present disclosure.

In this specification, a planar view corresponds to viewing from a direction perpendicular to the light incident surface of a semiconductor layer provided in a photoelectric conversion substrate. A sectional view corresponds to viewing a section perpendicular to the light incident surface of the semiconductor layer. Note that if the light incident surface of the semiconductor layer is rough microscopically, the plan view is defined with reference to the light incident surface of the semiconductor layer when viewed macroscopically.

In this specification, expressions “A or B”, “at least one of A and B”, “at least one of A or/and B”, and “one or more of A or/and B” and the like can include all possible combinations of the listed items unless otherwise explicitly defined. That is, the above expressions are understood to disclose all of a case where at least one A is included, a case where at least one B is included, and a case where at least one A and at least one B are included. This is similarly applied to combinations of three or more elements.

The contents disclosed in this specification include a complementary set of concepts described in this specification. That is, if, for example, “A is larger than B” is described in this specification, this specification is considered to disclose “A is not larger than B” even if a description of “A is not larger than B” is omitted. This is because if “A is larger than B” is described, it is assumed that a case where “A is not larger than B” has been considered.

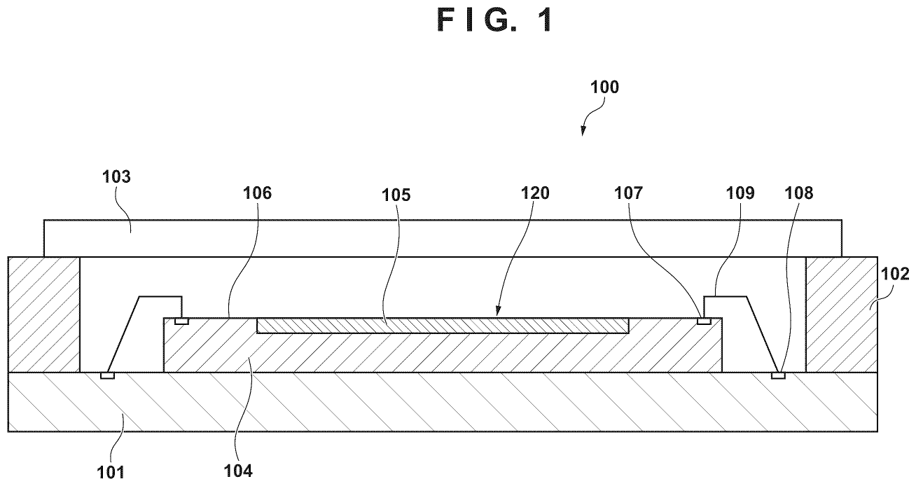

An electronic component according to an embodiment of the present disclosure will be described with reference to FIGS. 1 to 11. FIG. 1 is a sectional view showing an example of the arrangement of an electronic component 100 according to this embodiment. The electronic component 100 includes a support substrate 101, a photoelectric conversion substrate 104 fixed to the support substrate 101, and an optical member 103 arranged to face the photoelectric conversion substrate 104. The support substrate 101 and the optical member 103 are bonded via a frame body 102.

For the support substrate 101, for example, ceramic such as alumina or aluminum nitride can be used as a main material. Alternatively, for the support substrate 101, a material containing a resin such as glass epoxy may be used as a main material. In a case where the support substrate 101 is made of ceramic, it has high thermal conductivity and is thus advantageous in terms of heat dissipation. Alternatively, in a case where the support substrate 101 is made of a material containing a resin such as glass epoxy, it is advantageous in terms of weight reduction.

For the frame body 102, for example, ceramic such as alumina or aluminum nitride, glass epoxy, a resin material, a metal material, or the like is used, similar to the support substrate 101. In a case where the same material is used for the support substrate 101 and the frame body 102, such as a case where the support substrate 101 and the frame body 102 are made of ceramic, the support substrate 101 and the frame body 102 may be formed as one constituent material having a concave shape. That is, in the arrangement shown in FIG. 1, the support substrate 101 and the frame body 102 are formed separately, but the support substrate 101 and the frame body 102 may be formed integrally. Alternatively, in a case where different materials are used for the support substrate 101 and the frame body, for example, materials with linear expansion coefficients approximate each other may be selected as the materials of the support substrate 101 and the frame body 102 in terms of the bonding reliability between the support substrate 101 and the frame body 102.

For the optical member 103, for example, glass, quartz, sapphire, or the like can be used. In a case where quartz or sapphire is used for the optical member 103, the optical member 103 can also function as a low-pass filter (LPF) that transmits light of a predetermined wavelength or less. Sapphire has strength higher than that of quartz, and thus the optical member 103 can be thinned more than in a case where quartz is used. Therefore, in a case where sapphire is used for the optical member 103, this is advantageous in reducing the size of the overall electronic component 100. In addition, since the linear expansion coefficient of sapphire is roughly equal to that of alumina, if the frame body 102 is made of alumina and the optical member 103 is made of sapphire, the bonding reliability can be high. The optical member 103 may be applied with coating such as antireflection coating or infrared cut coating. From the viewpoint of suppressing reflection of light, both a surface, facing the photoelectric conversion substrate 104, of the optical member 103 and a surface on the opposite side may be applied with antireflection coating.

The photoelectric conversion substrate 104 includes a main surface 120 including a photoelectric conversion region 105 in which a plurality of photoelectric conversion elements are arranged and a peripheral region 106 in which electrodes 107 are arranged. Each electrode 107 is connected, via a conductive wire 109, to an electrode 108 arranged on the support substrate 101. In this embodiment, the photoelectric conversion substrate 104 is fixed to the main surface of the support substrate 101, on which the electrodes 108 are arranged. Therefore, the electrodes 107 are arranged at positions closer to the optical member 103 than the electrodes 108. As the photoelectric conversion substrate 104, for example, a semiconductor substrate such as a silicon substrate can be used. In a planar view, the photoelectric conversion region 105 is provided at the center of the photoelectric conversion substrate 104, and the plurality of photoelectric conversion elements are arranged in an array. Each photoelectric conversion element may be, for example, a normal photodiode or, for example, an avalanche photodiode. If the photoelectric conversion element is an avalanche photodiode, the avalanche photodiode may function as a Single Photon Avalanche Diode (SPAD) that quickly detects a faint signal of a single photon level.

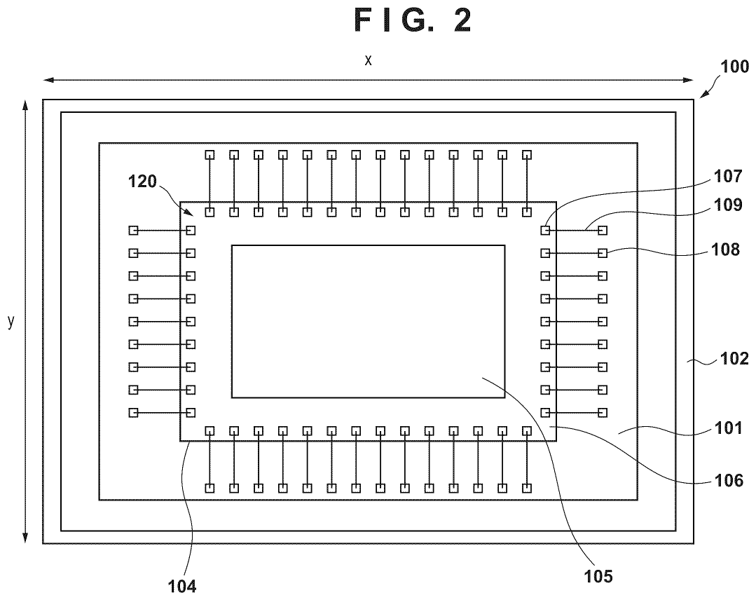

FIG. 2 is a plan view when viewed from the side of the optical member 103 of the electronic component 100 according to this embodiment. The photoelectric conversion region 105 of the photoelectric conversion substrate 104 is arranged at the center of the electronic component 100. The photoelectric conversion substrate 104 may have a rectangular shape, as shown in FIG. 2. The photoelectric conversion region 105 may also have a rectangular shape. The peripheral region 106 in which the plurality of electrodes 107 are arranged is arranged around the photoelectric conversion region 105. The plurality of conductive wires 109 are provided to electrically connect the plurality of electrodes 107 and the plurality of electrodes 108 arranged on the support substrate 101. When x and y represent the lengths in the longitudinal and widthwise directions of the electronic component 100, respectively, such electronic component 100 that x and y are about 10 mm to 60 mm is assumed. However, the size of the electronic component 100 is not limited to this.

In the electronic component 100 incorporating the photoelectric conversion substrate 104 including the photoelectric conversion elements, a phenomenon called a wire ghost in which incident light from the outside hits the conductive wire 109, is reflected by the conductive wire 109, enters the photoelectric conversion element, and is then reflected in an image may occur. In general, the conductive wire 109 is made of a metal such as gold, silver, aluminum, copper, or an alloy of these, and thus readily reflects light.

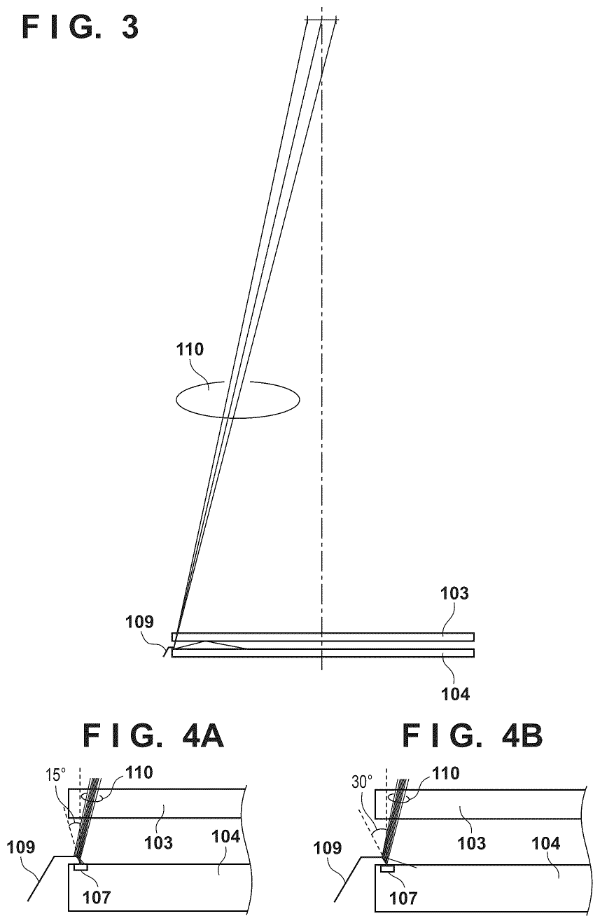

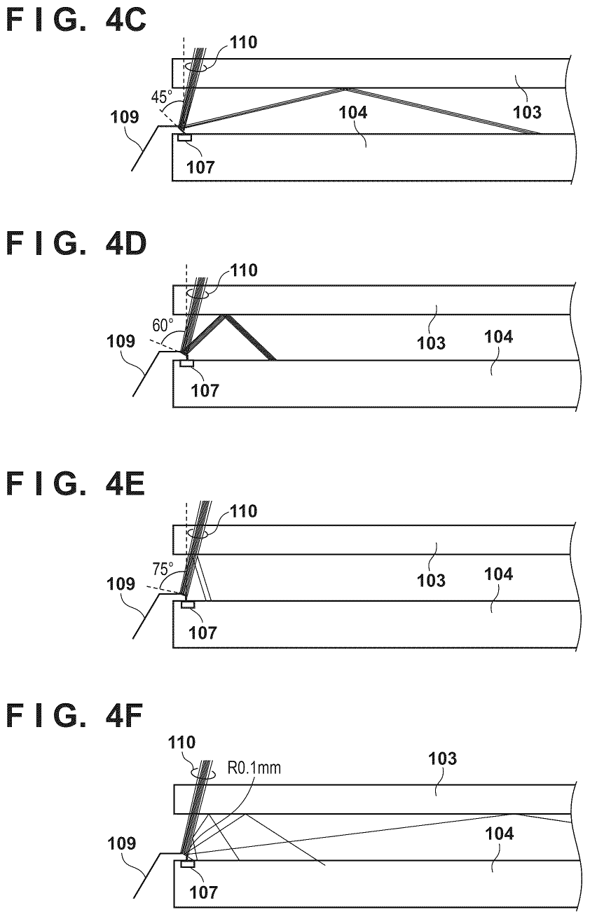

FIGS. 3 and 4A to 4F are schematic sectional views for explaining the wire ghost phenomenon. FIG. 3 shows a state in which incident light 110 entering from above the optical member 103 hits the conductive wire 109 to be reflected. Strictly, the incident light 110 passing through the optical member 103 changes its course in accordance with the refractive index of the optical member 103 but the incident light is shown as linear incident light for the sake of descriptive simplicity. FIGS. 4A to 4F are enlarged views showing the vicinity of the conductive wire 109 shown in FIG. 3.

FIG. 4A shows a state in which when θ represents an angle formed by the conductive wire 109 and the normal direction of the surface of the electrode 107, the conductive wire 109 rises from the electrode 107 while tilting at θ=15° on the outside of the photoelectric conversion substrate 104. The surface of the electrode 107 can be a surface parallel to the main surface 120 or the semiconductor layer forming the photoelectric conversion substrate 104. In the drawings of this specification, the surface of the electrode 107 and the main surface 120 of the photoelectric conversion substrate 104 are at the same height, but the electrode 107 may protrude from the main surface 120 of the photoelectric conversion substrate 104 by several μm or may be depressed.

While the incident light 110 that has hit the portion of θ=15° of the conductive wire 109 is reflected to enter the photoelectric conversion substrate 104, the reflected light enters a position close to the electrode 107. FIG. 4B shows a state in which the conductive wire 109 rises from the electrode 107 while tilting at θ=30° on the outside of the photoelectric conversion substrate 104. While the incident light 110 that has hit the portion of θ=30° of the conductive wire 109 is reflected to enter the photoelectric conversion substrate 104, the reflected light enters a position farther from the electrode 107 than in the case of θ=15° shown in FIG. 4A. FIG. 4C shows a state in which the conductive wire 109 rises from the electrode 107 while tilting at θ=45° on the outside of the photoelectric conversion substrate 104. While the incident light 110 that has hit the portion of θ=45° of the conductive wire 109 is reflected to travel toward the optical member 103, is reflected again by the surface facing the photoelectric conversion substrate 104 of the optical member 103, and then enters the photoelectric conversion substrate 104. In this case, the reflected light enters a position farther from the electrode 107 than in the case of θ=30° shown in FIG. 4B. Strictly, the reflected light includes a component that travels to the surface on the opposite side of the surface facing the photoelectric conversion substrate 104 of the optical member 103 and is reflected by the surface, but the component is weaker than the light reflected by the surface facing the photoelectric conversion substrate 104 and is thus not illustrated in FIG. 4C.

FIG. 4D shows a state in which the conductive wire 109 rises from the electrode 107 at θ=0° (in the normal direction of the surface of the electrode 107) and is then bent to tilt at θ=60° on the outside of the photoelectric conversion substrate 104. The incident light 110 that has hit the portion of θ=60° of the conductive wire 109 is reflected to travel toward the optical member 103, is reflected again by the surface facing the photoelectric conversion substrate 104 of the optical member 103, and then enters the photoelectric conversion substrate 104. In this case, the reflected light enters a position closer to the electrode 107 than in the case of θ=45° shown in FIG. 4C. FIG. 4E shows a state in which the conductive wire 109 rises from the electrode 107 at θ=0° and is then bent to tilt at θ=75° on the outside of the photoelectric conversion substrate 104. The incident light 110 that has hit the portion of θ=75° of the conductive wire 109 is reflected to travel toward the optical member 103, is reflected again by the surface facing the photoelectric conversion substrate 104 of the optical member 103, and then enters the photoelectric conversion substrate 104. In this case, the reflected light enters a position closer to the electrode 107 than in the case, shown in FIG. 4D, where the conductive wire 109 rises at θ=0° and is bent at θ=60°. FIG. 4F shows a state in which the conductive wire 109 rises from the electrode 107 at θ=0° and then is directed toward the outside of the photoelectric conversion substrate 104 while drawing an arc with a radius of curvature R=0.1 mm. The incident light 110 that has hit the bent portion having the round shape of the conductive wire 109 scatters at various angles depending on the position on the bent portion. Therefore, the reflected light is divided into components that directly enter the photoelectric conversion substrate 104 and components that are reflected by the optical member 103 at various angles and enter various positions of the photoelectric conversion substrate 104.

From the results shown in FIGS. 4A to 4F, if a portion around θ=45° with respect to the normal direction of the surface of the electrode 107 is included in the conductive wire 109, light that enters the photoelectric conversion substrate 104 at a position separated from the conductive wire 109 is increased. As a result, the possibility that light entering the photoelectric conversion region 105 where the plurality of photoelectric conversion elements are arranged is increased becomes high. Therefore, the wire ghost phenomenon highly likely occurs. It is also considered that the higher the height of the conductive wire 109 rising from the surface of the electrode 107, the more light that enters a position separated from the conductive wire 109. Furthermore, it is considered that the larger the distance between the photoelectric conversion substrate 104 and the optical member 103, the more light that enters a position separated from the conductive wire 109. Whether or not the wire ghost phenomenon occurs when the light reflected by the conductive wire 109 enters a position close to the conductive wire 109 is decided in accordance with the distance from the electrode 107 to the photoelectric conversion region 105. Whether or not the wire ghost phenomenon occurs when the light reflected by the conductive wire 109 enters a position far from the conductive wire 109 is related with the size of the photoelectric conversion region 105.

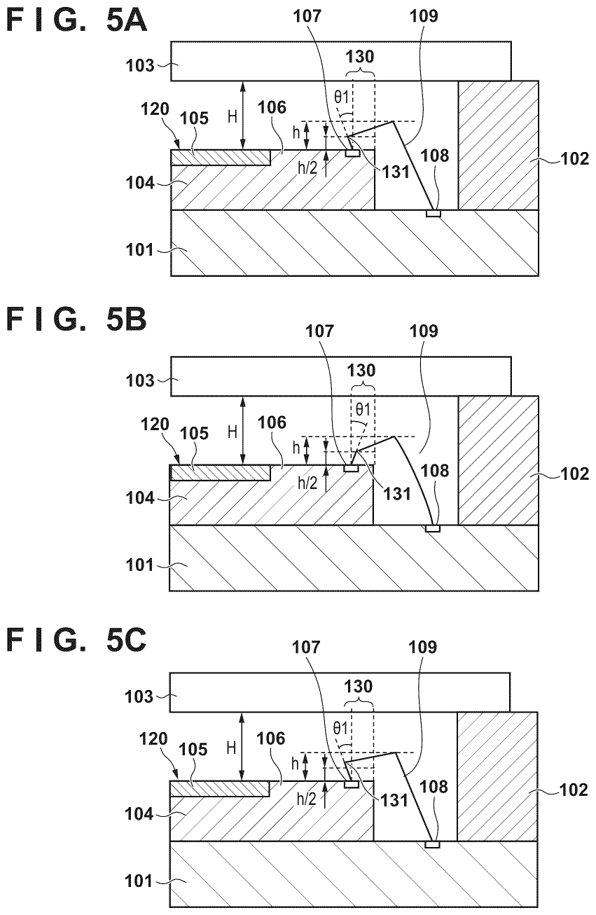

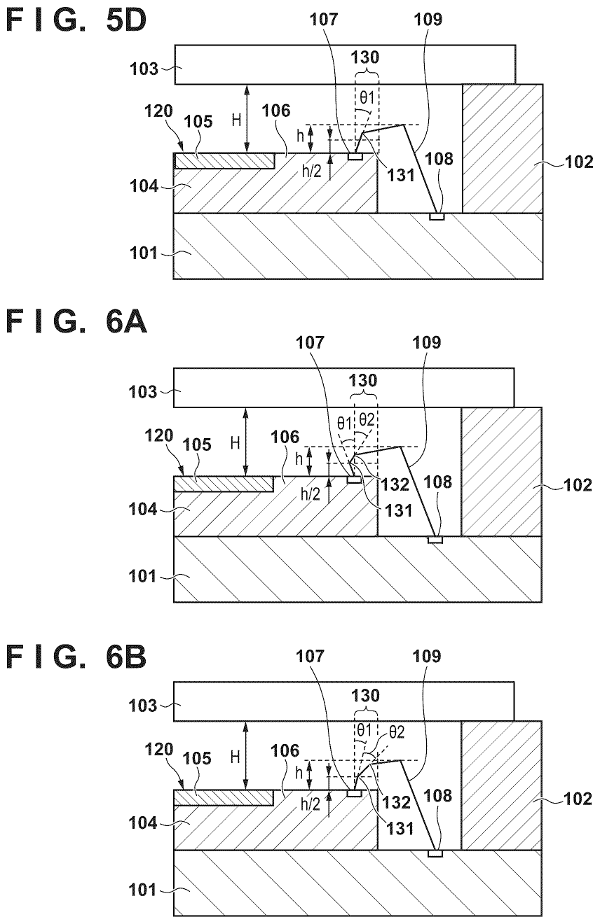

An arrangement for suppressing occurrence of the wire ghost phenomenon by causing the light reflected by the conductive wire 109 to enter a position close to the conductive wire 109 will be described below. FIGS. 5A to 5D are schematic views focusing on the conductive wire 109 of the electronic component 100. As shown in FIGS. 5A to 5D, the maximum height of the conductive wire 109 from the electrode 107 in the normal direction of the surface of the electrode 107 is represented by a height h. The height from the surface of the electrode 107 (or the main surface 120 of the photoelectric conversion substrate 104) to the optical member 103 in the normal direction is represented by a height H. A portion 130, arranged on the photoelectric conversion substrate 104, of the conductive wire 109 includes one or more bent portions 131. In this case, a portion, from the electrode 107 to at least a height h/2, of the portion 130 of the conductive wire 109 may have a maximum angle θ1 with respect to the normal direction of the surface of the electrode 107, which is 30° or less. The height h/2 indicates ½ of the maximum height h of the conductive wire 109 from the electrode 107 in the normal direction of the surface of the electrode 107. Light that hits a portion tilting at θ=30° of the portion 130 of the conductive wire 109 and is reflected enters the photoelectric conversion substrate 104 without being reflected on the side of the optical member 103.

Depending on the arrangement position of the conductive wire 109 and the design of an optical system that causes light to enter the electronic component 100, for example, light enters the conductive wire 109 while tilting at about 10° to 20° with respect to the normal direction of the surface of the electrode 107, as shown in FIGS. 3 and 4A to 4F. In this case, light that hits the portion, rising from the electrode 107 and tilting at θ=30°, of the portion 130 of the conductive wire 109 enters a position about 100 μm to 400 μm from the electrode 107 depending on the height (length) of the portion. On the other hand, the length between the electrode 107 and the photoelectric conversion region 105 is, for example, about 500 μm to 1,500 μm. Therefore, light that hits the portion, tilting at θ=30°, of the portion 130 of the conductive wire 109 and is reflected enters the peripheral region 106 of the photoelectric conversion substrate 104 without being reflected on the side of the optical member 103. As a result, occurrence of the wire ghost phenomenon can be suppressed.

Furthermore, a portion, from the electrode 107 to the bent portion 131 closest to the electrode 107, of the portion 130 of the conductive wire 109 may be arranged along the normal direction of the surface of the electrode 107 (θ1=0°), or may be arranged to tilt on the side of the photoelectric conversion region 105. Thus, light that hits the conductive wire 109 and is reflected enters a position closer to the conductive wire 109 of the photoelectric conversion substrate 104, thereby making it possible to suppress the wire ghost phenomenon. Furthermore, since the distance from the electrode 107 to the photoelectric conversion region 105 can be shortened, it is possible to reduce the size of the electronic component 100 (photoelectric conversion substrate 104).

The higher the height h of the conductive wire 109, the more a portion that reflects incident light. Therefore, the lower the height h is more suitable. For example, the conductive wire 109 may be arranged within the range of 200 μm or less from the surface of the electrode 107 in the normal direction of the surface of the electrode 107 (h≤200 μm). In a case where the height h of the conductive wire 109 is the same, light reflected by the conductive wire 109 and the optical member 103 readily enters a position farther from the electrode 107 as the height H is higher. Therefore, if the height H is large, reflected light may enter the photoelectric conversion region 105 to cause the wire ghost phenomenon. Thus, the height h may be ¾ or more of the height H (h≥0.75H).

In the arrangement shown in FIG. 5A, the conductive wire 109 rises from the electrode 107 to the height h/2 at θ1≤30° to tilt on the side of the photoelectric conversion region 105, and the bent portion 131 is provided at the height h/2, and extends toward the edge of the photoelectric conversion substrate 104. In the arrangement shown in FIG. 5B, the conductive wire 109 rises from the electrode 107 to the height h/2 at θ1≤30° to tilt on the side of the edge of the photoelectric conversion substrate 104, and the bent portion 131 is provided at the height h/2, and extends toward the edge of the photoelectric conversion substrate 104. A portion, separated from the electrode 107 more than the bent portion 131, of the portion 130 arranged on the photoelectric conversion substrate 104 of the conductive wire 109 may be arranged to separate more from the main surface 120 of the photoelectric conversion substrate 104 as the distance from the bent portion 131 increases, as shown in FIGS. 5A and 5B. In this case, as described above, if the portion, separated from the electrode 107 more than the bent portion 131, of the portion 130 of the conductive wire 109 has an angle of about 45° with respect to the normal direction of the surface of the electrode 107, light reflected by that portion is reflected again by the optical member 103. Furthermore, the light reflected by the optical member 103 can enter the photoelectric conversion substrate 104 at a position separated from the conductive wire 109. Therefore, the portion, separated from the electrode 107 more than the bent portion 131, of the portion 130 of the conductive wire 109 may have an angle falling outside the range of 40° (inclusive) to 50° (inclusive) with respect to the normal direction of the surface of the electrode 107. That is, the portion, separated from the electrode 107 more than the bent portion 131, of the portion 130 of the conductive wire 109 may have an angle larger than 50° and equal to or smaller than 90° with respect to the normal direction of the surface of the electrode 107. For example, the portion, separated from the electrode 107 more than the bent portion 131, of the portion 130 of the conductive wire 109 may have an angle larger than 0° and smaller than 40° with respect to the normal direction of the surface of the electrode 107. The description of the angle of the portion, separated from the electrode 107 more than the bent portion 131, of the portion 130 of the conductive wire 109 can apply to the portion, from the bent portion 131 to the height h, of the conductive wire 109.

In the arrangement shown in FIG. 5A and the arrangement shown in FIG. 5B, consider a case where the absolute value of the angle θ1, the height h, and the length from the electrode 107 to the portion at the height h of the conductive wire 109 in a planar view are the same. In this case, in the shape shown in FIG. 5A, the angle, with respect to the normal direction of the surface of the electrode 107, of the portion, from the height h/2 (bent portion 131) to the height h, of the conductive wire 109 is larger. In other words, the portion, from the height h/2 (bent portion 131) to the height h, of the conductive wire 109 approaches becoming horizontal to the surface of the electrode 107 (the main surface 120 of the photoelectric conversion substrate 104). Therefore, the incident light that hits the portion, from the bent portion 131 to the height h, of the conductive wire 109 is reflected by the conductive wire 109, is further reflected again by the optical member 103, and then enters a position close to the portion of the conductive wire 109 where the light has been reflected. That is, it is possible to suppress occurrence of the wire ghost phenomenon more in the arrangement shown in FIG. 5A than in the arrangement shown in FIG. 5B.

In each of arrangements shown in FIGS. 5C and 5D, the bent portion 131 closest to the electrode 107 is arranged at a position more than the height h/2 away from the surface of the electrode 107. It can be said that the bent portion 131 is arranged between the height h/2 and the height h. In the arrangement shown in FIG. 5C, the conductive wire 109 rises from the electrode 107 to the bent portion 131 at θ1≤30° to tilt on the side of the photoelectric conversion region 105, and extends from the bent portion 131 toward the edge of the photoelectric conversion substrate 104. In the arrangement shown in FIG. 5D, the conductive wire 109 rises from the electrode 107 to the bent portion 131 at θ1≤30° to tilt on the side of the edge of the photoelectric conversion region 105, and extends from the bent portion 131 toward the edge of the photoelectric conversion substrate 104. In each of the arrangements shown in FIGS. 5C and 5D as well, a portion, separated from the electrode 107 more than the bent portion 131, of the portion 130 of the conductive wire 109 may have an angle falling outside the range of 40° (inclusive) to 50° (inclusive) with respect to the normal direction of the surface of the electrode 107. That is, the portion, separated from the electrode 107 more than the bent portion 131, of the portion 130 of the conductive wire 109 may have an angle larger than 50° and equal to or smaller than 90° with respect to the normal direction of the surface of the electrode 107. For example, the portion, separated from the electrode 107 more than the bent portion 131, of the portion 130 of the conductive wire 109 may have an angle falling within the range of 0° (inclusive) to 40° (exclusive) with respect to the normal direction of the surface of the electrode 107.

In the arrangement shown in FIG. 5C and the arrangement shown in FIG. 5D, consider a case where the absolute value of the angle θ1, the height at which the bent portion 131 is located, the height h, and the length from the electrode 107 to the portion at the height h of the conductive wire 109 in a planar view are the same. In this case, in the shape shown in FIG. 5C, the angle, with respect to the normal direction of the surface of the electrode 107, of the portion, from the bent portion 131 to the height h, of the conductive wire 109 is larger. In other words, the portion, from the bent portion 131 to the height h, of the conductive wire 109 approaches becoming horizontal to the surface of the electrode 107 (the main surface 120 of the photoelectric conversion substrate 104). Therefore, the incident light that hits the portion, from the bent portion 131 to the height h, of the conductive wire 109 is reflected by the conductive wire 109, is further reflected again by the optical member 103, and then enters a position close to the portion of the conductive wire 109 where the light has been reflected. That is, it is possible to suppress occurrence of the wire ghost phenomenon more in the arrangement shown in FIG. 5C than in the arrangement shown in FIG. 5D.

Furthermore, from the same viewpoint, it is possible to suppress occurrence of the wire ghost phenomenon more in the arrangement shown in FIG. 5C than in the arrangement shown in FIG. 5A. It is also possible to suppress occurrence of the wire ghost phenomenon more in the arrangement shown in FIG. 5D than in the arrangement shown in FIG. 5B. Since the light that hits the portion, separated from the electrode 107 more than the bent portion 131, of the conductive wire 109 enters a position close to the portion of the conductive wire 109 where the light has been reflected, it can be said that the bent portion 131 closest to the electrode 107 is suitably arranged at a position close to the height h.

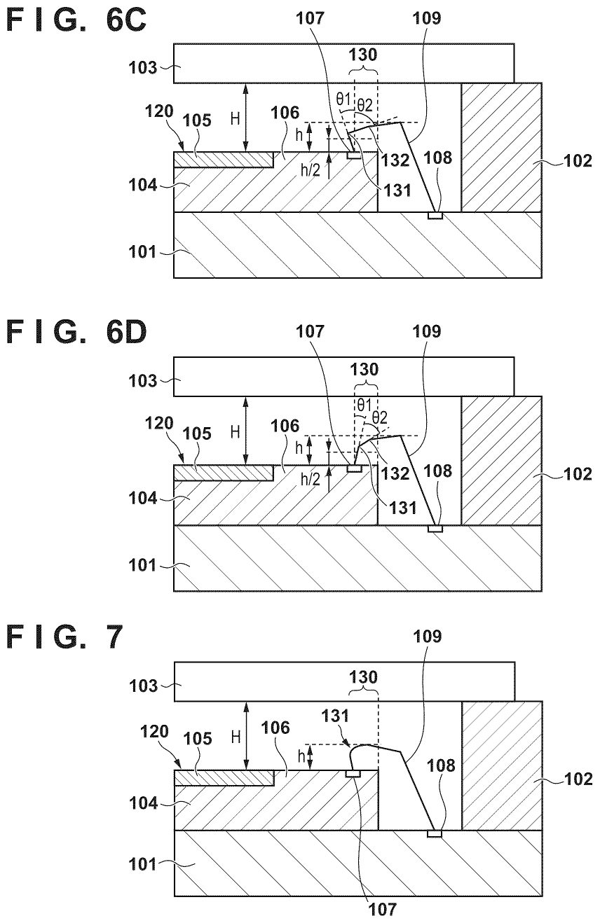

FIGS. 6A to 6D are views each showing a modification of the shape of the conductive wire 109. FIGS. 6A to 6D each show an example in which two bent portions including the bent portion 131 and a bent portion 132 are arranged in the portion 130 arranged on the photoelectric conversion substrate 104 of the conductive wire 109.

In an arrangement shown in FIG. 6A, the conductive wire 109 rises, at θ1≤30°, from the electrode 107 to the bent portion 131 located at the height h/2 to tilt on the side of the photoelectric conversion region 105. Next, the conductive wire 109 is bent at the bent portion 131 toward the edge of the photoelectric conversion substrate 104, and extends from the bent portion 131 to the bent portion 132 at an angle θ2 with respect to the normal direction of the surface of the electrode 107. Furthermore, the conductive wire 109 is bent at the bent portion 132, and extends toward the edge of the photoelectric conversion substrate 104. As described above, if the portion from the bent portion 131 to the bent portion 132 of the conductive wire 109 has the angle θ2 of about 45° with respect to the normal direction of the surface of the electrode 107, light reflected by the portion is reflected again by the optical member 103. Furthermore, the light reflected by the optical member 103 can enter the photoelectric conversion substrate 104 at a position separated from the conductive wire 109. The portion from the bent portion 131 to the bent portion 132 of the portion 130 of the conductive wire 109 is arranged to separate more from the main surface 120 of the photoelectric conversion substrate 104 as the distance from the bent portion 131 increases. In this case, the portion from the bent portion 131 to the bent portion 132 of the conductive wire 109 may have the angle θ2 with respect to the normal direction of the surface of the electrode 107, which need not fall within the range of 40° (inclusive) to 50° (inclusive). That is, the portion from the bent portion 131 to the bent portion 132 of the conductive wire 109 may have the angle θ2 with respect to the normal direction of the surface of the electrode 107, which falls within the range of 0° (inclusive) to 40° (exclusive), or the range of 50° (exclusive) to 90° (inclusive). It is possible to suppress occurrence of the wire ghost phenomenon more in a case where the angle θ2 is closer to 0° or 90°. The same applies to the portion, from the bent portion 132 to the height h, of the conductive wire 109. That is, the portion, from the bent portion 132 to the height h, of the conductive wire 109 can have the same angle as that of the portion, separated from the electrode 107 more than the bent portion 131, of the portion 130 of the conductive wire 109, which has been described with reference to FIGS. 5A to 5D.

In an arrangement shown in FIG. 6B, the conductive wire 109 rises at θ1≤30° from the electrode 107 to the bent portion 131 located at the height h/2 to tilt on the side of the edge of the photoelectric conversion substrate 104. The portion, from the bent portion 131 to the height h, of the conductive wire 109 can be same as in the arrangement shown in FIG. 6A. In each of arrangements shown in FIGS. 6C and 6D, the bent portion 131 closest to the electrode 107 is arranged at a position more than the height h/2 away from the surface of the electrode 107. In other words, the bent portion 131 is arranged between the height h/2 and the height h. The arrangements shown in FIGS. 6C and 6D can be same as those shown in FIGS. 6A and 6B except for the arrangement position of the bent portion 131.

In each of the arrangements shown in FIGS. 6A to 6D as well, it can be said that the bent portion 131 closest to the electrode 107 is suitably arranged at a position close to the height h. In addition, in each of the arrangements shown in FIGS. 6A to 6D, the bent portion 132 is arranged at a position lower than the height h. Therefore, the portion, separated from the electrode 107 more than the bent portion 132, of the portion 130 arranged on the photoelectric conversion substrate 104 of the conductive wire 109 is arranged to separate more from the main surface 120 of the photoelectric conversion substrate 104 as the distance from the bent portion 132 increases, but the present disclosure is not limited to this. The bent portion 132 may be arranged at the height h. In this case, the portion, separated from the electrode 107 more than the bent portion 132, of the portion 130 of the conductive wire 109 may extend at 90° with respect to the normal direction of the surface of the electrode 107, or may be arranged to become closer to the main surface 120 of the photoelectric conversion substrate 104 as the distance from the bent portion 132 increases.

In the portion 130 arranged on the photoelectric conversion substrate 104 of the conductive wire 109, three or more bent portions may be arranged. In this case, the conductive wire 109 rises from the electrode 107 to the bent portion 131 closest to the electrode 107 at θ1≤30°. After that, if the conductive wire 109 is arranged to separate more from the main surface 120 of the photoelectric conversion substrate 104 as the distance from the bent portion 131 increases, the conductive wire 109 can be formed until the height h is reached so that the angle with respect to the normal direction of the surface of the electrode 107 falls outside the range of 40° (inclusive) to 50° (inclusive). This can suppress occurrence of the wire ghost phenomenon.

FIG. 7 shows an example in which the portion 130 arranged on the photoelectric conversion substrate 104 of the conductive wire 109 includes the bent portion 131 having a round shape. In an arrangement shown in FIG. 7, the bent portion 131 closest to the electrode 107 has a round shape, but the present disclosure is not limited to this. For example, the bent portion 132 shown in each of FIGS. 6A to 6D may have a round shape. As shown in FIG. 7, the round shape of the bent portion 131 may include a portion located at the height h from the surface of the electrode 107 in the normal direction. As shown in FIG. 4F, light that hits the bent portion having the round shape scatters at various angles depending on the position where the light hits. Therefore, the reflected light is divided into components that directly enter the photoelectric conversion substrate 104 and components that are reflected by the optical member 103 at various angles and enter various positions of the photoelectric conversion substrate 104. As a result, occurrence of the wire ghost phenomenon can be suppressed.

In a case where a bent portion such as the bent portion 131 has a round shape, the radius of curvature of the round shape may be made small as much as possible so as to decrease light that hits the bent portion having the round shape. For example, it is understood that occurrence of the wire ghost phenomenon is experimentally, largely suppressed by setting the radius of curvature R to 0.16 mm or less. The radius of curvature R of the round shape may be 0.15 mm or less, 0.13 mm or less, or 0.12 mm or less.

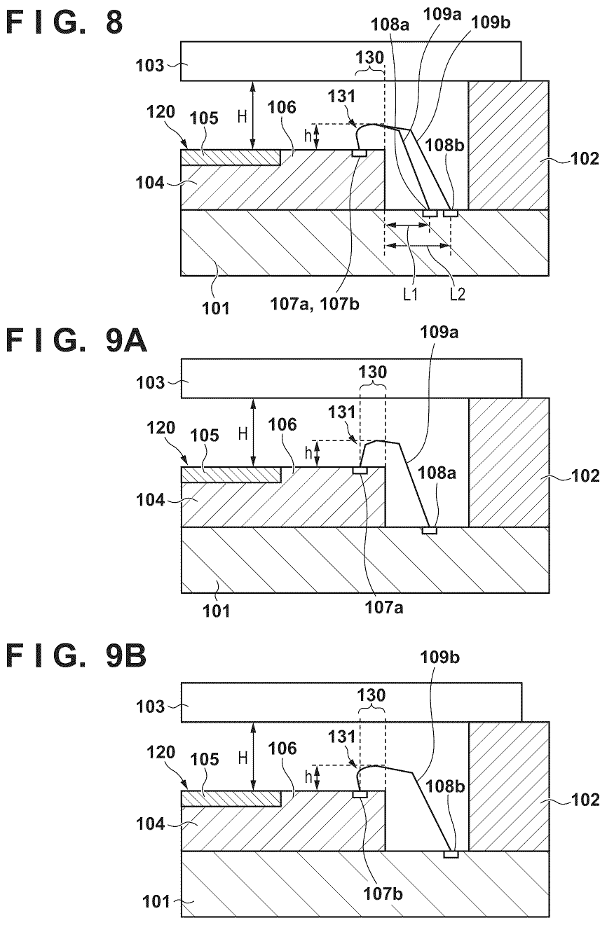

FIGS. 8, 9A, and 9B are views each showing a modification of the arrangement position of the electrode 108 arranged on the support substrate 101. In each of the above-described embodiments, the electrodes 108 arranged in correspondence with each side of the photoelectric conversion substrate 104 are arranged at positions of equal lengths from the edge of the photoelectric conversion substrate 104. For example, as shown in FIG. 2, all the electrodes 108 corresponding to each of the four sides of the photoelectric conversion substrate 104 may be arranged at positions of equal lengths from the edge of the photoelectric conversion substrate 104. On the other hand, in each of arrangements shown in FIGS. 8, 9A, and 9B, an electrode 108a is arranged at a position of a length L1 from the edge of the photoelectric conversion substrate 104, and an electrode 108b is arranged at a position of a length L2 longer than the length L1 from the edge of the photoelectric conversion substrate 104. The electrodes 108a and 108b may be electrodes arranged adjacent to each other among the plurality of electrodes 108. For example, the electrodes 108a and 108b may be alternately arranged in a staggered pattern along one side of the photoelectric conversion substrate 104.

The conductive wire 109 shown in FIG. 8 may have any of the shapes described above with reference to FIGS. 5A to 5D, 6A to 6D, and 7. As shown in FIG. 8, a conductive wire 109a that connects an electrode 107a and the electrode 108a and a conductive wire 109b that connects an electrode 107b and the electrode 108b may have the same shape in the portion 130 arranged on the photoelectric conversion substrate 104.

FIGS. 9A and 9B show an example in which the conductive wires 109a and 109b have different shapes. As shown in FIGS. 9A and 9B, one of the conductive wires 109a and 109b may be arranged to tilt on the side of the photoelectric conversion region 105 in the portion from the electrode 107a or 107b to the bent portion 131 closest to the electrode 107a or 107b among the bent portions. In the arrangement shown in FIGS. 9A and 9B, the conductive wire 109b connected to the electrode 108b arranged at a position separated from the edge of the photoelectric conversion substrate 104 more than the electrode 108a tilts on the side of the photoelectric conversion region 105 between the electrode 107 and the bent portion 131. However, the present disclosure is not limited to this, and the conductive wire 109a connected to the electrode 108a arranged at a position closer to the edge of the photoelectric conversion substrate 104 than the electrode 108b may tilt on the side of the photoelectric conversion region 105 between the electrode 107 and the bent portion 131.

The portions of the adjacent conductive wires 109a and 109b rising from the electrode 107 to the height h have different shapes. Thus, light entering the conductive wire 109a and light entering the conductive wire 109b are reflected in different directions. As a result, occurrence of the wire ghost phenomenon can be suppressed.

In the arrangement shown in FIGS. 9A and 9B, the electrodes 108a and 108b different in distance from the edge of the photoelectric conversion substrate 104 are arranged in a staggered pattern, and the conductive wire 109a connected to the electrode 108a and the conductive wire 109b connected to the electrode 108b have different shapes. However, the present disclosure is not limited to this, and even if the length between the electrodes 107 and 108 is the same, the adjacent conductive wires 109 may have different shapes. For example, by adjusting the length, tension, and the like of the conductive wire 109 in a wire bonding step, it is possible to arrange the conductive wires 109 having different shapes even if the length between the electrodes 107 and 108 is the same. The present disclosure is not limited to the arrangement in which the conductive wires 109 having different shapes are alternately arranged, and one or several conductive wires 109 having a different shape may be arranged for every several conductive wires 109. In the arrangement shown in FIGS. 9A and 9B, the conductive wires 109a and 109b having two different shapes are arranged, but the conductive wires 109 having three or more different shapes may be arranged.

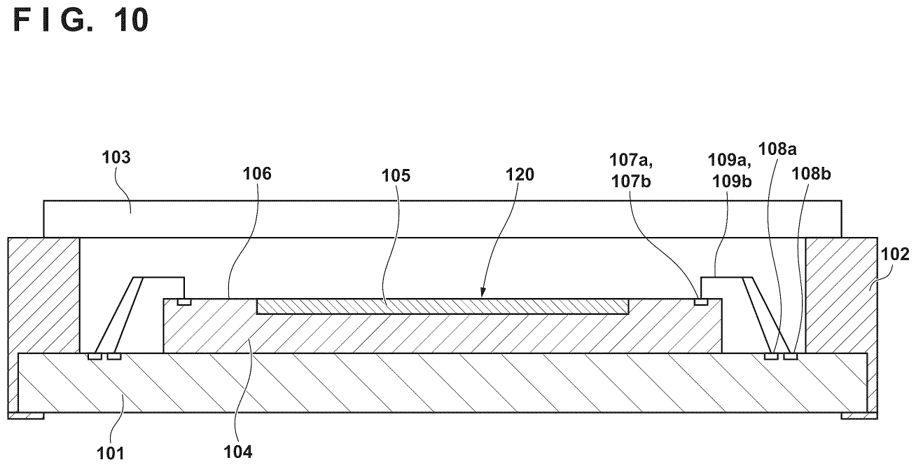

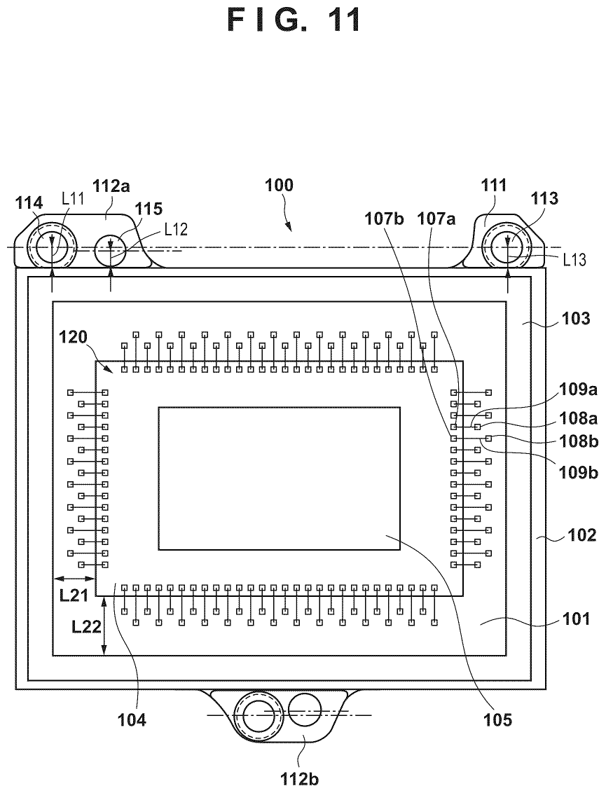

Next, a modification of the electronic component 100 will be described with reference to FIGS. 10 and 11. FIG. 10 is a sectional view showing an example of the arrangement of the electronic component 100 according to this embodiment. FIG. 11 is a plan view when viewed from the side of the optical member 103 of the electronic component 100. In the arrangement shown in FIGS. 10 and 11, the frame body 102 includes protruding portions 111 and 112 that protrude from sides of the frame body 102 in a planar view. In addition, the frame body 102 covers the outer edge of the support substrate 101, and also covers at least a part of the surface of the support substrate 101 on the opposite side of the surface that fixes the photoelectric conversion substrate 104. Since the remaining components may be the same as in each of the above-described embodiments, different components will mainly be described and a description of components that may be the same will be omitted appropriately.

As shown in FIG. 11, in a planar view, the protruding portions 111 and 112 are provided in the frame body 102 to protrude from at least two sides facing each other among the four sides of the rectangular shape of the frame body 102. In a planar view, a portion between the sides of the frame body 102 may be rounded as shown in FIG. 11, or may be chamfered, or the sides may intersect each other at a right angle. In the arrangement shown in FIG. 11, the protruding portions 111 and 112 are arranged to protrude from two sides arranged in the longitudinal direction of the frame body 102, but the present disclosure is not limited to this. The protruding portions 111 and 112 may be arranged on two sides facing each other in the widthwise direction, or may be arranged on three or more sides.

The protruding portions 111 and 112 can be used to, for example, fix the electronic component 100 to an external unit. One or more through holes 113 extending through the protruding portion 111 are formed in the protruding portion 111. Through holes 114 and 115 extending through the protruding portion 112 are formed in the protruding portion 112. For example, each of the through holes 113 and 114 can be a hole used to insert a screw or a bolt when fixing the electronic component 100 to the external unit using the screw or bolt. For example, the through hole 115 can be a hole used for positioning when fixing the electronic component 100 to the external unit. Therefore, the through holes 113 and 114 and the through hole 115 may have different shapes. For example, a step for receiving a screw head or nut can be formed in each of the through holes 113 and 114. Therefore, in a planar view, in the structure including the step, each of the through holes 113 and 114 can be larger than the through hole 115.

As shown in FIG. 11, the center of the through hole 114 arranged in the protruding portion 112 is arranged at a position of a length L11 from a virtual line obtained by extending the side on which the protruding portion 112 is arranged. The center of the through hole 115 arranged in the protruding portion 112 is arranged at a position of a length L12 from the virtual line obtained by extending the side on which the protruding portion 112 is arranged. The center of the through hole 113 arranged in the protruding portion 111 is arranged at a position of a length L13 from a virtual line obtained by extending the side on which the protruding portion 111 is arranged. At this time, the lengths L11 and L12 may be different from each other. If the lengths L11 and L12 are equal to each other, the protruding portion 112 may become large in a direction in which the through holes 114 and 115 are arranged. For example, as described above, each of the through holes 113 and 114 can be formed to be larger than the through hole 115 because of its structure. The through holes 113 and 114 are formed so that the length L11 is longer than the length L12. This may be able to reduce the size of the outer shape of the protruding portion 112 and reduce the size of the electronic component 100. In a case where the length L11 is longer than the length L12, the size of the electronic component 100 can be reduced more than in a case where the length L11 is shorter than the length L12. The lengths L11 and L13 may be equal to each other, as shown in FIG. 11. This is because the through holes 113 and 114 can be formed in the same size (shape).

As described above, the protruding portions 111 and 112 arranged in the frame body 102 can be used to fix the electronic component 100 to the external unit. On the other hand, when the protruding portions 111 and 112 are arranged in the frame body 102, the support substrate 101 bonded to the frame body 102 may be partially warped or partially changed in shape. Thus, the shape of the conductive wire 109 may be adjusted appropriately in accordance with the position where the conductive wire 109 is arranged. By adjusting the shape of the conductive wire 109 appropriately, it is possible to suppress a failure in which, for example, a tensile stress is applied to the conductive wire 109 due to a partial warp of the support substrate 101 or the like and the conductive wire 109 is thus disconnected. Similar to the above-described arrangement shown in FIG. 8, in the arrangement shown in FIGS. 10 and 11, the plurality of electrodes 108 arranged on the support substrate 101 are arranged in a staggered pattern. However, the present disclosure is not limited to this, and as the shape of the conductive wire 109 and the arrangement of the electrodes 108, the shape and the arrangement of each of the above-described embodiments can be applied. Even if the protruding portions 111 and 112 are arranged in the frame body 102, it is possible to suppress the wire ghost phenomenon by using the above-described shape as the shape of the conductive wire 109.

As shown in FIG. 11, protruding portions 112a and 112b may be arranged on two sides facing each other. The protruding portions 112a and 112b may have the same shape. At this time, as shown in FIG. 11, only one protruding portion 112b arranged on one side of the frame body 102 may be arranged at the center of the side. The center of the side may indicate, for example, two portions contacting the center of the side in a case where one side is divided into four portions. Alternatively, for example, the center of the side may indicate a portion including the center of the side in a case where one side is divided into three parts. In a case where only one protruding portion 111 or 112 is arranged on one side, the protruding portion 111 or 112 is arranged at the center of the side. This can suppress a warp or a deformation such as a twist of the frame body 102 or the support substrate 101 bonded to the frame body 102. As shown in FIG. 11, in a case where the protruding portions 111 and 112a are arranged on one side, they may be arranged at positions of equal lengths from the center of the side. For example, the difference between the length from the center of the side on which the protruding portions 111 and 112a are arranged to the center of the through hole 113 of the protruding portion 111 and the length from the center of the side on which the protruding portions 111 and 112a are arranged to the center of the through hole 113 of the protruding portion 112a may be 20% or less of the length of the side. Alternatively, for example, the difference between the length from the center of the side on which the protruding portions 111 and 112a are arranged to the center of the through hole 113 of the protruding portion 111 and the length from the center of the side on which the protruding portions 111 and 112a are arranged to the center of the through hole 113 of the protruding portion 112a may be 10% or less of the length of the side. Alternatively, for example, the length from the center of the side on which the protruding portions 111 and 112a are arranged to the center of the through hole 113 of the protruding portion 111 and the length from the center of the side on which the protruding portions 111 and 112a are arranged to the center of the through hole 114 of the protruding portion 112a may be equal to each other. This can suppress a warp or a deformation such as a twist of the frame body 102 or the support substrate 101 bonded to the frame body 102. In a case where three or more protruding portions 111 and 112 are arranged on one side, they may be arranged, for example, at equal intervals. The interval between the protruding portions 111 and 112 may be defined by, for example, the length of a portion of the side, in which no protruding portions are provided, or the length between the centers of the through holes having the same shape.

For the photoelectric conversion substrate 104 mounted on the electronic component 100, a distribution in a heat generation amount may occur in plane. For example, in a case where each of the electrodes 107 arranged along the longitudinal direction of the electronic component 100 functions as an output terminal for outputting a signal from the photoelectric conversion substrate 104, the heat generation amount of each of the electrodes 107 arranged along the longitudinal direction can be large. The number of signal input/output operations when the photoelectric conversion substrate 104 operates changes depending on the function of the electrode 107, and the heat generation amount thus changes. To cope with this, as shown in FIG. 11, the length between the frame body 102 and the photoelectric conversion substrate 104 may be different between the longitudinal direction and the widthwise direction of the electronic component 100 in a planar view. In the arrangement shown in FIG. 11, a length L21 between the frame body 102 and the photoelectric conversion substrate 104 in the longitudinal direction is shorter than a length L22 between the frame body 102 and the photoelectric conversion substrate 104 in the widthwise direction. In other words, the length L22 between the frame body 102 and the edge of the photoelectric conversion substrate 104 on which the electrodes 107 with large heat generation amounts along the longitudinal direction are arranged is longer than the length L21 between the frame body 102 and the edge of the photoelectric conversion substrate 104 on which the electrodes 107 along the widthwise direction are arranged. This can reserve a heat dissipation space. For example, a heat dissipation member such as a heat dissipation sheet may be arranged in the heat dissipation space reserved between the electrodes 108 and the frame body 102. When thermal conduction to the frame body 102 is inhibited, it is possible to suppress a deformation of the frame body 102 and the like.

In the arrangement shown in FIG. 11, the length L22 is longer than the length L21. However, the present disclosure is not limited to this, and the length L22 may be shorter than the length L21 in accordance with the function of each of the plurality of electrodes 107, the heat generation distribution of the photoelectric conversion substrate 104, and the like.

In the arrangement shown in FIG. 10, the support substrate 101 and the frame body 102 are formed separately. However, the present disclosure is not limited to this, and the support substrate 101 and the frame body 102 may be formed integrally. In the arrangement of the support substrate 101 and the frame body 102 shown in FIGS. 1 and 2 as well, the protruding portions 111 and 112 may be arranged in the frame body 102.

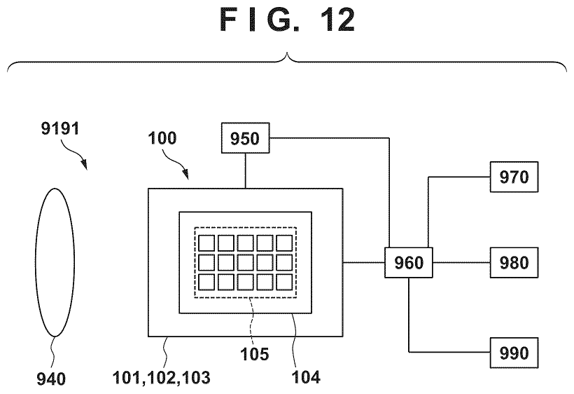

An application example of the electronic component 100 according to this embodiment will now be explained with reference to FIG. 12. FIG. 12 is a schematic view of an apparatus 9191 including the electronic component 100. The apparatus 9191 can include at least one of an optical device 940, a control device 950, a processing device 960, a display device 970, a storage device 980, and a mechanical device 990. The optical device 940 is implemented by, for example, a lens, a shutter, and a mirror. The control device 950 controls, for example, the photoelectric conversion substrate 104 arranged in the electronic component 100. The control device 950 is, for example, a semiconductor device such as an ASIC.

The processing device 960 processes a signal output from the photoelectric conversion substrate 104 arranged in the electronic component 100. The processing device 960 is a semiconductor device such as a CPU or an ASIC for forming an analog front end (AFE) or a digital front end (DFE). The display device 970 is an EL display device or a liquid crystal display device that displays information (image) obtained by the photoelectric conversion substrate 104. The storage device 980 is a magnetic device or a semiconductor device that stores the information (image) obtained by the photoelectric conversion substrate 104. The storage device 980 is a volatile memory such as an SRAM or a DRAM, or a nonvolatile memory such as a flash memory or a hard disk drive.

The mechanical device 990 includes a moving or propulsion unit such as a motor or an engine. In the apparatus 9191, the signal output from the photoelectric conversion substrate 104 arranged in the electronic component 100 is displayed on the display device 970 or transmitted to an external device by a communication device (not shown) included in the apparatus 9191. Hence, the apparatus 9191 may further include the storage device 980 and the processing device 960 in addition to the memory circuits and arithmetic circuits included in the photoelectric conversion substrate 104. The mechanical device 990 may be controlled based on the signal output from the photoelectric conversion substrate 104.

In addition, the apparatus 9191 is suitable for an electronic apparatus such as an information terminal (for example, a smartphone or a wearable terminal) which has an image capturing function or a camera (for example, an interchangeable lens camera, a compact camera, a video camera, or a monitoring camera). The mechanical device 990 in the camera can drive the components of the optical device 940 in order to perform zooming, an in-focus operation, and a shutter operation. Alternatively, the mechanical device 990 in the camera can move the electronic component 100 in which the photoelectric conversion substrate 104 is arranged in order to perform an anti-vibration operation.

Furthermore, the apparatus 9191 can also be applied to an onboard camera mounted in a transportation apparatus such as a vehicle, a ship, an airplane, or an industrial robot. The mechanical device 990 in the transportation apparatus can be used as a moving device. The apparatus 9191 as the transportation apparatus is suitable for a device that transports the electronic component 100 in which the photoelectric conversion substrate 104 is arranged or a device that uses an image capturing function to assist and/or automate driving (steering). The processing device 960 for assisting and/or automating driving (steering) can perform, based on the information obtained by the photoelectric conversion substrate 104, processing for operating the mechanical device 990 as a moving device. The apparatus 9191 incorporating the electronic component 100 in which the photoelectric conversion substrate 104 is arranged can be widely applied to an apparatus using object recognition such as an intelligent transport system (ITS), in addition to the transportation apparatus. Alternatively, the apparatus 9191 may be a medical apparatus such as an endoscope, a measurement apparatus such as a distance measurement sensor, an analysis apparatus such as an electron microscope, or an office apparatus such as a copy machine.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2024-074047, filed Apr. 30, 2024, which is hereby incorporated by reference herein in its entirety.

What is claimed is:

1. An electronic component comprising a support substrate, a photoelectric conversion substrate fixed to the support substrate, and an optical member arranged to face the photoelectric conversion substrate,
wherein the photoelectric conversion substrate includes a main surface including a photoelectric conversion region in which a plurality of photoelectric conversion elements are arranged and a peripheral region in which a first electrode is arranged,
the first electrode is connected, via a conductive wire, to a second electrode arranged on the support substrate,
a first portion, arranged on the photoelectric conversion substrate, of the conductive wire includes at least one bent portion,
the conductive wire is arranged within a range of not more than 200 μm from a surface of the first electrode in a normal direction of the surface, and
a portion, from the first electrode to a first height, of the first portion has a maximum angle not larger than 30° with respect to the normal direction where the first height is ½ of a maximum height of the conductive wire from the surface in the normal direction.

2. The component according to claim 1, wherein a first bent portion closest to the first electrode among the bent portions is arranged at a position more than the first height away from the surface.

3. The component according to claim 2, wherein a portion, from the first electrode to the first bent portion, of the first portion is arranged along the normal direction or arranged to tilt on a side of the photoelectric conversion region.

4. The component according to claim 2, wherein a portion, separated from the first electrode more than the first bent portion, of the first portion is arranged to separate more from the main surface as a distance from the first bent portion increases, and an angle with respect to the normal direction falls outside a range of not less than 40° and not more than 50°.

5. The component according to claim 2, wherein
the bent portions include the first bent portion and a second bent portion, and
a portion, from the first bent portion to the second bent portion, of the first portion is arranged to separate more from the main surface as a distance from the first bent portion increases, and an angle with respect to the normal direction falls outside a range of not less than 40° and not more than 50°.

6. The component according to claim 5, wherein
the second bent portion is arranged at a position lower than the maximum height from the surface in the normal direction, and
a portion, separated from the first electrode more than the second bent portion, of the first portion is arranged to separate more from the main surface as a distance from the second bent portion increases.

7. The component according to claim 5, wherein the second bent portion is arranged at a position of the maximum height from the surface in the normal direction.

8. The component according to claim 1, wherein the bent portions include a bent portion having a round shape.

9. The component according to claim 2, wherein the first bent portion has a round shape.

10. The component according to claim 2, wherein
the first bent portion has a round shape, and
the round shape includes a portion located at the maximum height from the surface in the normal direction.

11. The component according to claim 8, wherein a radius of curvature of the round shape is not more than 0.16 mm.

12. The component according to claim 1, wherein the maximum height is not less than ¾ of a height from the surface to the optical member in the normal direction.

13. The component according to claim 1, wherein the first electrode is arranged at a position closer to the optical member than the second electrode.

14. The component according to claim 1, wherein
a plurality of first electrodes including the first electrode, a plurality of second electrodes including the second electrode, and a plurality of conductive wires including the conductive wire are arranged,
the plurality of second electrodes include a third electrode and a fourth electrode arranged adjacent to each other, and
in a planar view, the third electrode is arranged at a position of a first length from an edge of the photoelectric conversion substrate, and the fourth electrode is arranged at a position of a second length longer than the first length from the edge of the photoelectric conversion substrate.

15. The component according to claim 14, wherein one of the conductive wire connected to the third electrode among the plurality of conductive wires and the conductive wire connected to the fourth electrode among the plurality of conductive wires is arranged to tilt on a side of the photoelectric conversion region in a portion from the first electrode to the bent portion closest to the first electrode among the bent portions.

16. The component according to claim 15, wherein the conductive wire connected to the fourth electrode among the plurality of conductive wires is arranged to tilt on the side of the photoelectric conversion region in the portion from the first electrode to the bent portion closest to the first electrode among the bent portions.

17. The component according to claim 14, wherein
the plurality of second electrodes include a plurality of third electrodes including the third electrode and a plurality of fourth electrodes including the fourth electrode, and
the third electrodes and the fourth electrodes are alternately arranged.

18. An apparatus comprising:
the electronic component according to claim 1; and
a processing device configured to process a signal output from the photoelectric conversion substrate.
